(19) United States
(12) Patent Application Publication
(10) Pub. No.: US 2023/0049164 A1
(43) Pub. Date: Feb. 16, 2023

(54) METHOD FOR MANUFACTURING BONDED SUBSTRATE, BONDED SUBSTRATE, AND LIQUID DISCHARGE HEAD

(71) Applicants: Yoshiyuki TOYOTA, Kanagawa (JP); Keishi MIWA, Kanagawa (JP)

(72) Inventors: Yoshiyuki TOYOTA, Kanagawa (JP); Keishi MIWA, Kanagawa (JP)

(21) Appl. No.: 17/870,863

(22) Filed: Jul. 22, 2022

(30) Foreign Application Priority Data
Jul. 27, 2021 (JP) 2021-122522
Oct. 12, 2021 (JP) 2021-167354

(51) Int. Cl. H01L 21/18; H01L 21/304; H01L 27/20; B41J 2/14

(52) U.S. Cl. CPC H01L 21/187; H01L 21/304; H01L 27/20; B41J 2/14233; B41J 2002/14258

(57) ABSTRACT

A method for manufacturing a bonded substrate, the method includes: bonding a first mother substrate including a first substrate and a second mother substrate including a second substrate to form a bonded mother substrate; cutting off a part of the first mother substrate along a dividing line of the bonded mother substrate to form a cutoff portion; dividing the bonded mother substrate along the dividing line; separating a bonded substrate from the bonded mother substrate, the bonded substrate including the first substrate and the second substrate bonded to the first substrate; forming a contact terminal on an end portion of the first mother substrate, the contact terminal contactable with an external terminal; forming a communication path between the first mother substrate and the second mother substrate along the dividing line.

### CROSS-REFERENCE TO RELATED APPLICATIONS

This patent application is based on and claims priority pursuant to 35 U.S.C. § 119(a) to Japanese Patent Application No. 2021-122522, filed on Jul. 27, 2021, in the Japan Patent Office, and Japanese Patent Application No. 2021-167354, filed on Oct. 12, 2021, in the Japan Patent Office, the entire disclosures of which are hereby incorporated by reference herein.

### BACKGROUND

### Technical Field

Aspects of the present disclosure relate to a method for manufacturing bonded substrate, a bonded substrate, and a liquid discharge head.

### Related Art

A manufacturing method for manufacturing a bonded substrate includes a separating step. The separating step separates the bonded mother substrate along a dividing line and cuts off the bonded substrate from the bonded mother substrate. The bonded mother substrate includes the first mother substrate and the second mother substrate bonded with each other. The bonded substrate includes the first substrate and the second substrate bonded with each other.

### SUMMARY

A method for manufacturing a bonded substrate, the method includes: bonding a first mother substrate including a first substrate and a second mother substrate including a second substrate to form a bonded mother substrate; cutting off a part of the first mother substrate along a dividing line of the bonded mother substrate to form a cutoff portion; dividing the bonded mother substrate along the dividing line; separating a bonded substrate from the bonded mother substrate, the bonded substrate including the first substrate and the second substrate bonded to the first substrate; forming a contact terminal on an end portion of the first mother substrate, the contact terminal contactable with an external terminal; forming a communication path between the first mother substrate and the second mother substrate along the dividing line; forming a structure in the communication path between the cutoff portion and the contact terminal; and applying a protective layer material on the bonded mother substrate from the cutoff portion to form a protective layer.

A bonded substrate includes: a first substrate; a second substrate bonded to the first substrate; a contact terminal on an end portion of the first substrate in a short side direction of the first substrate, the contact terminal contactable with an external terminal; a protective layer covering the first substrate and the second substrate; a cutoff portion in a part of the first substrate along a dividing line in a longitudinal direction of the bonded substrate, the cutoff portion configured to expose the second substrate in a plan view of the bonded substrate viewed from the first substrate; and a structure connecting the first substrate and the second substrate, the structure disposed between the cutoff portion and the contact terminal in a longitudinal direction orthogonal to the short side direction.

A bonded substrate includes: a first substrate; a second substrate bonded to the first substrate; a contact terminal on an end portion of the first substrate in a short side direction of the first substrate, the contact terminal contactable with an external terminal; a protective layer covering the first substrate and the second substrate; a cutoff portion in a part of the second substrate along a dividing line in a longitudinal direction of the bonded substrate, the cutoff portion configured to expose the second substrate in a plan view of the bonded substrate viewed from the second substrate; and a structure connecting the first substrate and the second substrate, the structure disposed between the cutoff portion and the contact terminal in a longitudinal direction orthogonal to the short side direction.

A liquid discharge head includes the bonded substrate.

### BRIEF DESCRIPTION OF THE DRAWINGS

A more complete appreciation of the disclosure and many of the attendant advantages and features thereof can be readily obtained and understood from the following detailed description with reference to the accompanying drawings, wherein:

FIG. 1 is a perspective view of a portion of an internal structure of a liquid discharge head according to the embodiments of the present disclosure;

FIG. 2 is a top plan view of an actuator substrate forming the liquid discharge head;

FIG. 3 is a cross-sectional view of the liquid discharge head along line A-A′ in FIG. 2;

FIG. 4 is a cross-sectional view of the liquid discharge head along line C-C′ in FIG. 2;

FIG. 5 is a cross-sectional view of a variation of a piezoelectric element, in which a lower electrode is an individual electrode layer, and an upper electrode is a common electrode layer;

FIGS. 6A to 6D are cross-sectional views of the liquid discharge head orthogonal to a nozzle array direction to explain a front stage of a manufacturing process of the liquid discharge head;

FIGS. 7A to 7C are cross-sectional views of the liquid discharge head orthogonal to the nozzle array direction to explain a middle stage of the manufacturing process of the liquid discharge head;

FIGS. 8A to 8D are cross-sectional views of the liquid discharge head orthogonal to the nozzle array direction to explain a later stage of a manufacturing process of the liquid discharge head;

FIG. 9A is a schematic plan view of a first silicon substrate including an actuator substrate;

FIG. 9B is a schematic plan view of a second silicon substrate including a holding substrate;

FIG. 10 is an enlarged schematic plan view of one actuator substrate formed on the first silicon substrate;

FIG. 11(a) is a schematic plan view of a bonded silicon substrate in which the first silicon substrate and the second silicon substrate are bonded, and FIG. 11(b) is a partial enlarged plan view of the bonded silicon substrate of FIG. 11(a);

FIG. 12A is a cross-sectional view of the bonded silicon substrates according to Comparative Example 1 along a chip short side on the dividing line;

FIG. 12B is a partial cross-sectional view of the bonded silicon substrate according to Comparative Example 1 along a chip long side on the dividing line;

FIG. 13A is a cross-sectional view of the bonded silicon substrates according to the present embodiment along the chip short side on the dividing line;

FIG. 13B is a partial cross-sectional view of the bonded silicon substrate according to the present embodiment along the chip long side on the dividing line;

FIG. 14A is a cross-sectional view of the bonded silicon substrates according to another example of the present embodiment along the chip short side on the dividing line;

FIG. 14B is a partial cross-sectional view of the bonded silicon substrate according to another example of the present embodiment along the chip long side on the dividing line;

FIG. 15(a) is a schematic plan view of the bonded silicon substrate according to Comparative Example 2, and FIG. 15(b) is a partial enlarged plan view of the bonded silicon substrate of FIG. 15(a);

FIG. 16A is a cross-sectional view of the bonded silicon substrates according to Comparative Example 2 along the chip short side on the dividing line;

FIG. 16B is a cross-sectional view of the bonded silicon substrates according to Comparative Example 2 along the chip long side on the dividing line;

FIG. 17 is a plan view of an example of a portion of a liquid discharge apparatus according to the present embodiments;

FIG. 18 is a schematic side view of an example of a liquid discharge device;

FIG. 19 is a schematic plan view of a portion of another example of the liquid discharge device; and

FIG. 20 is a front view of a liquid discharge device according to an embodiment of the present disclosure.

The accompanying drawings are intended to depict embodiments of the present invention and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION OF EMBODIMENTS

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a”, “an”, and “the” are intended to include the plural forms as well, unless the context clearly indicates otherwise.

It will also be understood that when an element is referred to as being “connected” or “coupled” to another element, it can be directly connected or coupled to another element or intervening elements may be present.

In contrast, when an element is referred to as being “directly connected” or “directly coupled” to another element, there are no intervening elements present. Referring now to the drawings, wherein like reference numerals designate identical or corresponding parts throughout the several views, embodiments of the present disclosure are described below.

Hereinafter, an embodiment in which the present disclosure is applied to a bonded substrate. The bonded substrate is used for manufacturing an electromechanical conversion substrate in a liquid discharge head of an inkjet recording apparatus as an image forming apparatus. The image forming apparatus is an example of a liquid discharge apparatus. Hereinafter, “a liquid discharge head” is simply referred to as a “head”.

First, a configuration of a head 10 is described below.

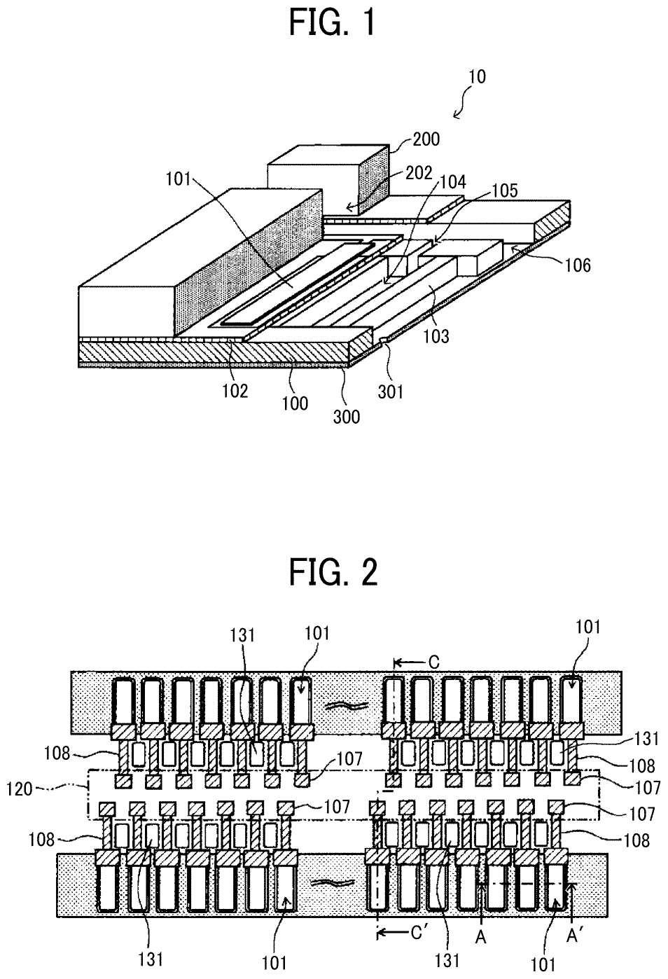

FIG. 1 is a perspective view of a portion of an internal structure of the head 10 according to a first embodiment of the present disclosure.

FIG. 2 is a top view of an actuator substrate 100 forming the head 10.

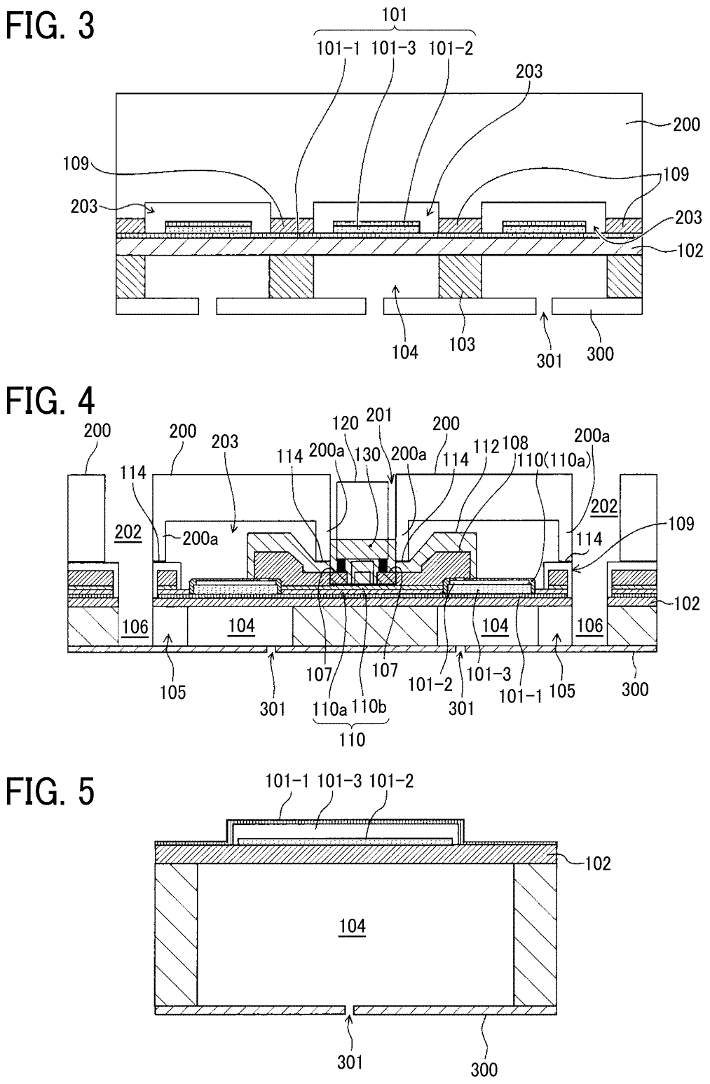

FIG. 3 is a cross-sectional view of the head 10 along line A-A′ in FIG. 2.

FIG. 4 is a cross-sectional view of the head 10 along line C-C′ in FIG. 2.

In FIG. 2, the holding substrate 200 bonded on the actuator substrate 100 is removed for an explanation.

The head 10 according to the first embodiment mainly includes an actuator substrate 100 formed of a first substrate, a holding substrate 200 formed of a second substrate, and a nozzle substrate 300. The actuator substrate 100 includes a piezoelectric element 101 as an electromechanical transducer element that generates energy to discharge liquid. The piezoelectric element 101 is formed on an element mounting surface (upper surface in FIG. 1) of a diaphragm 102 as a displacement plate.

As illustrated in FIG. 3, the piezoelectric element 101 of the first embodiment includes a piezoelectric layer 101-3 sandwiched between a common electrode layer 101-1 as a lower electrode and an individual electrode layer 101-2 as an upper electrode. However, as illustrated in FIG. 5, a piezoelectric element 101 may include a lower electrode as the individual electrode layer 101-2 and an upper electrode as the common electrode layer 101-1.

Further, the actuator substrate 100 includes a partition wall 103 on a surface (lower surface in FIG. 1) of the diaphragm 102 opposite to the element mounting surface of the diaphragm 102. A space surrounded by the diaphragm 102, the partition wall 103, and the nozzle substrate 300 becomes a pressure chamber 104. Further, the actuator substrate 100 forms a fluid restrictor 105 and a common chamber 106.

The holding substrate 200 includes an ink supply port to supply ink from an ink cartridge. The holding substrate 200 adhered (bonded) to the actuator substrate 100 forms a common channel 202 and a recess 203. The recess 203 forms a space in which the diaphragm 102 of the actuator substrate 100 is bendable and displaceable. The holding substrate 200 can be formed by silicon etching, plastic molding or the like.

Further, nozzles 301 are formed in the nozzle substrate 300 at positions corresponding to the respective pressure chambers 104. The nozzle substrate 300 may be formed by punching, etching, silicon etching, nickel electroforming, resin laser processing, or the like on a plate made of SUS, for example.

The head 10 of the first embodiment applies a drive voltage signal from the drive integrated circuit (drive IC 120) to each individual electrode layers 101-2 under a control of a controller with the ink filled in each of the pressure chambers 104.

As the drive voltage signal, a pulse voltage of 20 [V] generated by an oscillation circuit may be used. With an application of the pulse voltage to the piezoelectric layer 101-3, the piezoelectric layer 101-3 contracts in a direction parallel to the diaphragm 102 due to a piezoelectric effect. As a result, the diaphragm 102 bends to protrude toward the pressure chamber 104 side (downward in FIG. 3). A pressure in the pressure chamber 104 rapidly rises, and ink is discharged from the nozzles 301 communicating with the pressure chamber 104.

After the pulse voltage is applied to the piezoelectric layer 101-3, the piezoelectric layer 101-3 returns from a shrank position to an original position. Accordingly, the diaphragm 102 displaced also returns from a shrank position to an original position. Thus, an interior of the pressure chamber 104 becomes a negative pressure as compared with a pressure inside an interior of the common chamber 106. Thus, the ink supplied from the ink cartridge via the ink supply port is supplied from the common channel 202 and the common chamber 106 to the pressure chamber 104 via the fluid restrictor 105. The head 10 repeats the processes as described above to enable a continuous discharge of ink droplets so that an image is formed on a recording material disposed opposite the head 10.

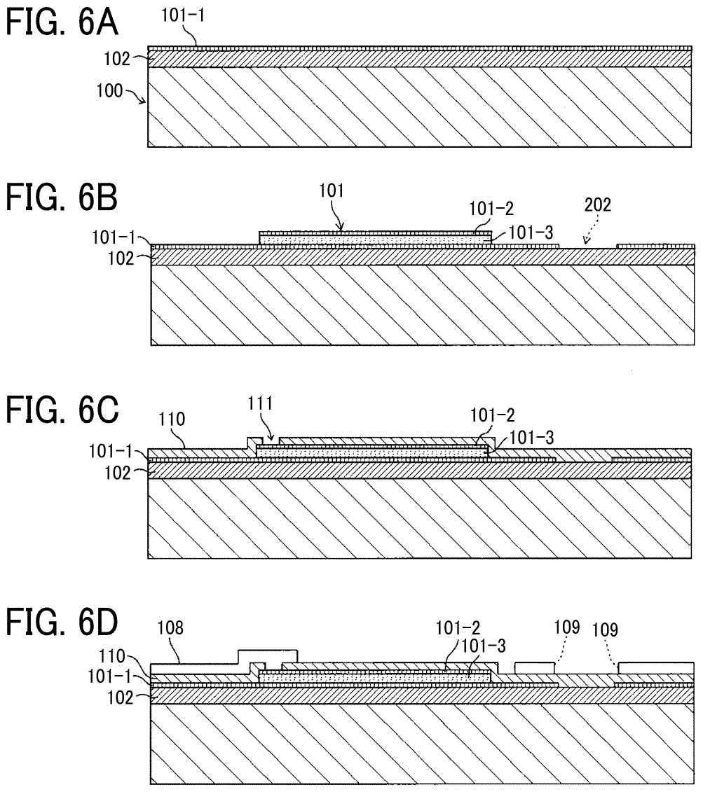

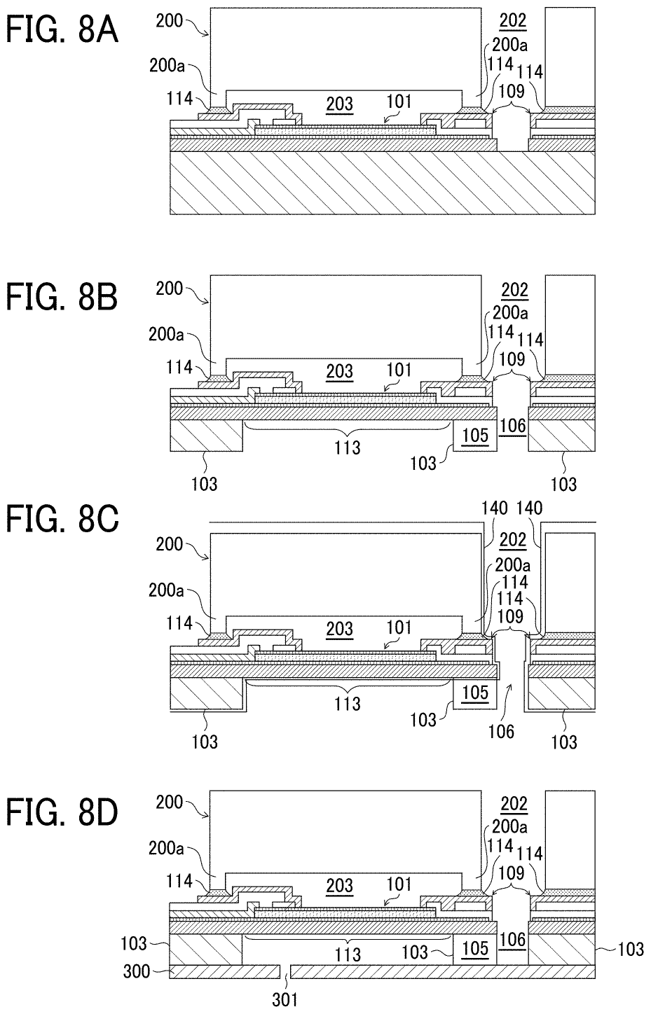

Next, a method of manufacturing the head 10 according to the first embodiment is described below with reference to FIGS. 6A to 6D, to FIGS. 8A to 8D.

FIGS. 6A to 6D, 7A to 7C, and 8A to 8C are cross-sectional views of the head 10 orthogonal to an arrangement direction of the nozzles 301 to describe a manufacturing process of the head 10 according to the first embodiment of the present disclosure.

As a base material of the actuator substrate 100, a silicon single crystal substrate is preferably used as a first mother substrate (first silicon substrate). The silicon single crystal substrate usually preferably has a thickness of 100 to 600 μm. The silicon single crystal substrate has three types of plane orientations of (100), (110), and (111). However, the plane orientations of (100) and (111) are widely used in a semiconductor industry in general. The single crystal substrate mainly having a plane orientation of (100) is used in the present embodiment. Further, the silicon single crystal substrate is processed by etching in a step of forming the pressure chamber 104 in the actuator substrate 100.

Anisotropic etching is typically used as a method of etching the silicon single crystal substrate to form the pressure chamber 104. The anisotropic etching utilizes a property in which an etching rate is different according to plane orientations of crystal structure of the silicon single crystal substrate.

For example, an etching rate of the plane orientation of (111) is about 1/400 of an etching rate of the plane orientation of (100) in anisotropic etching that immerses the silicon single crystal substrate in an alkaline solution such as KOH. Therefore, while a structure having an inclination of about 54° can be produced in the plane orientation (100), a deep groove can be formed in the plane orientation (110).

Thus, an arrangement density can be increased while maintaining rigidity. Thus, a single crystal substrate having a plane orientation of (110) may also be used for the actuator substrate 100. However, SiO₂ as a mask material is also etched during an etching process when the single crystal substrate having a plane orientation of (110) is used so that attention should be paid to this etching of SiO₂ as the mask material.

First, as illustrated in FIG. 6A, a film to become the diaphragm 102 is formed on the silicon single crystal substrate (actuator substrate 100).

The diaphragm 102 repeatedly deforms under a force generated by the piezoelectric element 101. Thus, the diaphragm 102 preferably has sufficient strength to withstand a repeated deformation. Examples of material include Si, SiO₂, and Si₃N₄ prepared by a chemical vapor deposition (CVD). Further, the diaphragm 102 is preferably made of material selected from a material having a linear expansion coefficient close to a linear expansion coefficient of the individual electrode layer 101-2 and the piezoelectric layer 101-3 to be bonded to the diaphragm 102.

A material of lead zirconate titanate (PZT) is used as the piezoelectric layer 101-3 in the present embodiment. Thus, a material having a linear expansion coefficient of 5×10⁻⁶ to 10×10⁻⁶ (1/K) close to a linear expansion coefficient 8×10⁻⁶ (1/K) of the PZT is preferably used for the diaphragm 102. Furthermore, a material having a linear expansion coefficient of 7×10⁻⁶ to 9×10⁻⁶ (1/K) is more preferable.

Specific examples of the materials of the diaphragm 102 include aluminum oxide, zirconium oxide, iridium oxide, ruthenium oxide, tantalum oxide, hafnium oxide, osmium oxide, rhenium oxide, rhodium oxide, palladium oxide, and compounds of the foregoing materials. Using such materials, the diaphragm 102 can be produced by a spin coater using a sputtering or a sol-gel method.

The film thickness is preferably in a range from 0.1 to 10 μm and is more preferably in a range from 0.5 to 3 μm. If the film thickness of the diaphragm 102 is smaller than the range from 0.1 to 10 μm, it is difficult to process the pressure chamber 104. If the film thickness of the diaphragm 102 is greater than the range from 0.1 to 10 μm, the diaphragm 102 may be less deformed and displaced, thus hampering stable discharge of ink droplets.

Next, a common electrode layer 101-1 is formed on the diaphragm 102 formed in the above-described manner. The common electrode layer 101-1 preferably includes a metal film single layer or a multilayer structure of a metal film and an oxide film. In any case, an adhesion layer is preferably inserted between the diaphragm 102 and the metal film to reduce peeling, of the common electrode layer 101-1 from the diaphragm 102, or the like.

As the adhesion layer, titanium (Ti) is deposited (film-formed) by sputtering, and a titanium film is thermally oxidized in an O₂ atmosphere at temperature from 650° C. to 800° C. for one to thirty minutes using a rapid thermal annealing (RTA) apparatus to transform the titanium film to a titanium oxide film. Reactive sputtering may be used to prepare the titanium oxide film.

However, a thermal oxidation method of the titanium film at high temperature is more preferable to prepare the titanium oxide film. The fabrication of the titanium oxide film by the reactive sputtering needs to heat the silicon substrate at a high temperature. Thus, a special sputtering chamber to heat the silicon substrate is required.

Further, oxidation by the RTA apparatus provides better crystallinity of the titanium oxide film than oxidation by a general heating furnace. If the oxidation by the general heating furnace is used, a titanium film which is easy to be oxidized forms multiple crystal structures at low temperatures.

Thus, the multiple crystal structures of the titanium film has to be destroyed once. Therefore, the oxidation by RTA apparatus with a fast temperature rise is more advantageous to form good crystals. As a material other than titanium (Ti), materials such as tantalum (Ta), iridium (Ir), ruthenium (Ru), for example, are also preferable.

The film thickness is preferably from 10 nm to 50 nm and is more preferably from 15 nm to 30 nm. If the film thickness is below the above-described range (from 10 nm to 50 nm), an adhesion may be reduced. If the film thickness is over the above-described range (from 10 nm to 50 nm), quality of crystal of an electrode film to be formed on the adhesion layer may be deteriorated.

As a metal film for forming the common electrode layer 101-1, platinum having high heat resistance and low reactivity has been used. Platinum may not have sufficient barrier properties against lead in some cases. Thus, platinum group elements such as iridium and platinum-rhodium and alloy films of platinum group elements may be used as the metal material for the metal film for forming the common electrode layer 101-1.

Adhesion of platinum with a base (in particular, SiO₂) may be poor. Therefore, the adhesion layer as described-above is preferably laminated in advance on the base. As a method of manufacturing the metal film, vacuum film deposition (vacuum film-forming) such as a sputtering or a vacuum vapor deposition is generally used. The film thickness of the metal film is preferably from 80 to 200 nm and is more preferably from 100 to 150 nm.

If the film thickness of the metal film is thinner than 80 to 200 nm, the metal film may be difficult to supply a sufficient current as a common electrode. Thus, a problem occurs in a head during discharging an ink from a head.

Further, if the film thickness of the metal film is thicker than 80 to 200 nm, cost for manufacturing the common electrode layer 101-1 increases when an expensive material of the platinum group element is used. If platinum is used as material, a surface roughness increases as the film thickness increases. Increase in the surface roughness of the common electrode layer 101-1 influences the surface roughness and crystal orientation of the oxide electrode film or PZT. Thus, the diaphragm 102 may not sufficiently displaced for discharging ink.

SrRuO₃ is preferably used as material of a metal oxide film for preparing the common electrode layer 101-1. Instead of SrRuO₃, material as described as Sr_{X}A₍₁₋ₓ₎Ru_{y}B_{(1-y)} such as (A=Ba, Ca, B=Co, Ni, x, y=0 to 0.5) may be used for the metal oxide film for forming the common electrode layer 101-1. The sputtering may be adopted to form the metal oxide film. The film quality of a SrRuO₃ thin-film changes depending on the sputtering conditions. Particularly, it is preferable to heating the substrate at a film formation temperature of 500° C. or higher to form the metal oxide film in order to orient the SrRuO₃ thin-film in (111) plane along with Pt (111) plane used for the metal film with emphasis on crystal orientation.

A lattice constant of Pt is close to a lattice constant of SrRuO₃, and thus 2θ position of SrRuO₃ (111) and 2θ position of Pt (111) overlap in usual 2θ/θ measurement. Thus, crystallinity of the SrRuO₃ thin-film formed on Pt (111) is difficult to distinguish. A diffraction intensity of Pt cannot be seen at 2θ position at about 32° in a Psi direction inclined by 35° because a diffraction lines cancel each other according to the extinction rule. Thus, it is possible to confirm whether SrRuO₃ is preferentially oriented to (111) by determining a peak intensity of 2θ at about 32° by tilting the Psi direction by about 35°. When Psi direction is tilted while 2θ is fixed to 2θ=32°, almost no diffraction intensity of SrRuO₃ (110) is observed at Psi=0°, and the diffraction intensity of SrRuO₃ (110) is observed at the vicinity of Psi=35°. Thus, it is confirmed that SrRuO₃ is oriented in (111) plane with respect to the metal film prepared under the film forming conditions of the present embodiment. The diffraction intensity of SrRuO₃ (110) is observed at Psi=0° for the SrRuO₃ film thus manufactured.

It is estimated that an amount of degradation in a displacement amount of the piezoelectric element 101, after the piezoelectric element 101 is continuously driven and displaced for a predetermined time, from an initial displacement amount of the piezoelectric element 101. The orientation of PZT is very influential, and (110) plane is insufficient in suppressing degradation of displacement of PZT. Furthermore, when the surface roughness of the SrRuO₃ thin-film is observed, the surface roughness is influenced by the film formation temperature. The surface roughness of the SrRuO₃ thin-film is a small value of 2 nm or less from room temperature to 300° C. When the surface roughness of the SrRuO₃ thin-film is 2 nm or less, although the surface of the SrRuO₃ film is very flat, the crystallinity of the SrRuO₃ thin-film is not sufficient. Thus, sufficient characteristics may not be obtained in the initial displacement amount and displace amount after the continuous driving of the piezoelectric element 101 formed on the SrRuO₃ thin-film.

The surface roughness of the SrRuO₃ film is preferably 4 nm to 15 nm and is more preferably 6 nm to 10 nm. If the surface roughness of the SrRuO₃ film is greater than a range of 4 nm to 15 nm, the dielectric strength voltage of a subsequently formed PZT film decrease so that the PZT film easily leaks. Therefore, it is preferable to perform film-formation of the piezoelectric element 101 at a film-forming temperature in a range from 500° C. to 700° C. and is more preferably from 520° C. to 600° C. to obtain good crystallinity and surface roughness. The surface roughness is based on a surface roughness (average roughness) measured by an atomic force microscope (AFM) as an index.

A composition ratio of Sr and Ru (Sr/Ru) after film-forming the SrRuO₃ film is preferably 0.82 or more and 1.22 or less. If the composition ratio Sr/Ru is out of the above-described range (0.82 or more and 1.22 or less), a resistivity of the SrRuO₃ film increases, and sufficient conductivity may not be obtained as the common electrode layer 101-1. The film thickness of the SrRuO₃ film is preferably from 40 nm to 150 nm and is more preferably from 50 nm to 80 nm. If the film thickness of the SrRuO₃ film is thinner than the above-described range (from 40 nm to 150 nm), a sufficient characteristic in an initial displace amount and displace amount after the continuous driving may not be obtained.

Further, the SrRuO₃ film may not function as a stop etching layer to reduce over-etching of PZT film. Conversely, if the film thickness of the SrRuO₃ film is thicker than the above-described range (from 40 nm to 150 nm), a dielectric breakdown voltage of a PZT film formed on the SrRuO₃ film decreases, and the PZT film easily leaks. Further, the resistivity of the SrRuO₃ film is preferably 5×10⁻³ Ωcm or less and is more preferably 1×10⁻³ Ωcm or less.

If the resistivity of the SrRuO₃ film is larger than the above-described range (5×10⁻³ Ωcm or less), a contact resistance increases at an interface between the SrRuO₃ film as the common electrode layer 101-1 and an electrode in contact with the common electrode layer 101-1. Thus, the SrRuO₃ film cannot supply a sufficient current as the common electrode layer 101-1, and a trouble occurs during discharging the ink.

Next, as illustrated in FIG. 6B, the piezoelectric layer 101-3 is formed on the common electrode layer 101-1. PZT is used as the material of the piezoelectric layer 101-3 in the present embodiment. The PZT is a solid solution of lead zirconate (PbZrO₃) and lead titanate (PbTiO₃) and has different characteristics according to a ratio of the lead zirconate (PbZrO₃) and the lead titanate (PbTiO₃) in the solution. When a ratio of PbZrO₃ and PbTiO₃ is 53:47, the PZT has a generally excellent piezoelectric property.

A composition of the PZT is represented by a chemical formula of Pb (Zr0.53, Ti0.47)O₃, generally, PZT(53/47). An example of a composite oxide other than the PZT is barium titanate. In such a case, barium alkoxide and titanium alkoxide compounds are used as a starting material and are dissolved in a common solvent, to prepare a barium titanate precursor solution. The above-described materials are represented by a general formula of ABO₃ and are corresponded to composite oxides including A=Pb, Ba, Sr, and B=Ti, Zr, Sn, Ni, Zn, Mg, and Nb as main components.

A specific description of the composite oxide is, for example, (Pb1-x, Ba) (Zr, Ti) O₃, (Pb1-x, Sr) (Zr, Ti) O₃. The specific description of (Pb1-x, Ba) (Zr, Ti) O₃, (Pb1-x, Sr) (Zr, Ti) O₃ means that Pb of A site is partially replaced with Ba or Sr. The substitution of Pb to Ba or Sr is enabled by a bivalent element, and the substitution has an effect to reduce deterioration of characteristic occurred by an evaporation of lead during heat treatment.

The piezoelectric layer 101-3 can be prepared by a spin coater using sputtering or a Sol-gel method. When the sputtering or the Sol-gel method is used to prepare the piezoelectric layer 101-3, a desired pattern is obtained by photolithographic etching because patterning is necessary.

When PZT is prepared by the Sol-gel method, lead acetate, zirconium alkoxide, titanium alkoxide compound is used as a starting material, and the starting material is dissolved in methoxyethanol as a common solvent to obtain a homogeneous solution, and thus a PZT precursor solution can be prepared. A metal alkoxide compound is more easily hydrolyzed by moisture in the atmosphere, and thus a stabilizer such as acetylacetone, acetic acid, diethanolamine or the like may be added as a stabilizer to the precursor solution in an appropriate amount.

To form the PZT film on a whole surface of a base substrate, a coating film is formed on the base substrate by a solution coating method such as spin coating, and the coating film is subjected to each of heat treatments such as solvent drying, thermal decomposition, and crystallization. Transformation from the coating to a crystalline film causes volume contraction. Thus, it is preferable to adjust the precursor concentration so that a film thickness of 100 nm or less can be obtained in a single step to obtain a crack-free film. A layer thickness of the piezoelectric layer 101-3 is preferably from 0.5 to 5 μm and is more preferably from 1 μm to 2 μm. If the layer thickness of the piezoelectric layer 101-3 is smaller than the above-described range (from 0.5 to 5 μm), the piezoelectric layer 101-3 may not sufficiently displaced. If the layer thickness of the piezoelectric layer 101-3 is larger than the above-described range (from 0.5 to 5 μm), many layers has to be laminated to prepare the piezoelectric layer 101-3, and thus the number of steps for preparing the piezoelectric layer 101-3 increases, and the process time increases.

Further, the dielectric constant of the piezoelectric layer 101-3 is preferably 600 or more and 2000 or less, and is more preferably 1200 or more and 1600 or less. If the dielectric constant (relative permittivity) of the piezoelectric layer 101-3 is smaller than the above-described range (600 or more and 2000 or less), the piezoelectric layer 101-3 may not exhibit sufficient displacement characteristics. If the dielectric constant (relative permittivity) of the piezoelectric layer 101-3 is larger than the above-described range (600 or more and 2000 or less), the polarization treatment may not be sufficiently performed on the piezoelectric layer 101-3. Thus, the piezoelectric layer 101-3 may be difficult to obtain sufficient displacement characteristics due to deterioration of displacement after continuous driving of the piezoelectric element 101.

As illustrated in FIG. 6B, after the piezoelectric layer 101-3 is formed on the common electrode layer 101-1, the individual electrode layer 101-2 is film-formed on the piezoelectric layer 101-3. Similarly to the common electrode layer 101-1, the individual electrode layer 101-2 also preferably includes a metal film single layer or a multilayer including a metal film and an oxide film.

As the oxide film, an oxide film described for the common electrode layer 101-1 can be used. The film thickness of the SrRuO₃ film as the oxide film is preferably from 20 nm to 80 nm and is more preferably from 40 nm to 60 nm. As the metal film, the metal film described for the common electrode layer 101-1 can be used. The film thickness of the metal film is preferably from 30 to 200 nm and is more preferably from 50 to 120 nm.

Next, as illustrated in FIG. 6C, an interlayer insulating film 110 is formed on the common electrode layer 101-1 to insulate the common electrode layer 101-1 and the piezoelectric element 101 from a leading wiring 108 to be formed on the interlayer insulating film 110. Further, the interlayer insulating film 110 has to be made of a dense inorganic material since the interlayer insulating film 110 functions to prevent damage to the piezoelectric element 101 occurred during film formation and etching processes.

Further, a material of the interlayer insulating film 110 has to be selected from a material that is difficult to permeate moisture in the atmosphere, and thus the dense inorganic material is used as the material of the interlayer insulating film 110. An organic material is not suitable as material of the interlayer insulating film 110 because the organic material is necessary to increase the film thickness to obtain sufficient protection performance.

The organic material is not suitable as material of the interlayer insulating film 110 because the deformation of the diaphragm 102 may be hampered when the interlayer insulating film 110 is made thick, and thus an inkjet head having low discharge performance may be formed by using the organic material.

As the interlayer insulating film 110, it is preferable to use an oxide, a nitride, a carbonized film, for example, to obtain a high protective performance with a thin film. Thus, it is preferable to select a material having high adhesiveness to the electrode material, the piezoelectric material, and the diaphragm material that is to be the base of the interlayer insulating film 110. Also, a film-forming method that does not damage the piezoelectric element 101 may be selected. That is, it is not preferable to use a plasma chemical vapor deposition (CVD) or a sputtering.

In the CVD, a reactive gas is converted into a plasma and deposited on a substrate. In the sputtering method, a plasma is discharged and collided with a target material to be film-formed on the target material. As a preferable film-forming method, there are a vapor deposition, an atomic layer deposition (ALD), and the like. The ALD is more preferable since the ALD has a wide selection of usable materials. Preferred materials include oxide film used for ceramic material such as Al₂O₃, ZrO₂, Y₂O₃, Ta₂O₃, and TiO₂, for example. Particularly, usage of the ALD can prepare a thin film having a high film density and can reduce a damage to the piezoelectric element 101 occurred during the film-forming process.

The interlayer insulating film 110 has to be sufficiently thick to ensure a protection performance of the piezoelectric element 101. At the same time, the interlayer insulating film 110 has to be made as thin as possible so as not to hamper (hinder) a displacement (deformation) of the diaphragm 102. Therefore, the preferable range of the film thickness of the interlayer insulating film 110 is from 20 nm to 100 nm. When the thickness of the interlayer insulating film 110 is greater than 100 nm, the amount of deformation (displacement) of the diaphragm 102 decreases, so that the inkjet head has low discharge efficiency. Conversely, when the thickness of the interlayer insulating film 110 is less than 20 nm, the interlayer insulating film 110 insufficiently functions as a protective layer of the piezoelectric element 101, so that the performance of the piezoelectric element 101 decreases.

Alternatively, the interlayer insulating film 110 may have a two-layer structure. In this case (the interlayer insulating film 110 having the two-layer structure), the thickness of a second layer of the insulating protective film (second insulating protective film 110b) is increased as illustrated in FIG. 4. The second insulating protective film 110b may be removed in an overlapping portion in which the second insulating protective film 110b overlaps with the piezoelectric element 101 or in a vicinity of the overlapping portion. Thus, only a first layer of the insulating protective film (first insulating protective film 110a) is formed in the overlapping portion or in the vicinity of the overlapping portion so that the second insulating protective film 110b does not hamper the displacement (deformation) of the diaphragm 102.

Any oxide, nitride, carbide or a complex compound of oxide, nitride, and carbide may be used for the second insulating protective film 110b if the second insulating protective film 110b is removed in the vicinity of the overlapping portion. SiO₂ generally used in semiconductor devices may be used for the second insulating protective film 110b. Any method such as the CVD and the sputtering can be used for film-forming the insulating protective film 110b. Considering coating a step of a pattern forming part such as an electrode forming part, it is preferable to use the CVD capable of isotropically forming a film.

The thickness of the interlayer insulating film 110 may be formed such that the interlayer insulating film 110 is not broken by the voltage applied between the common electrode layer 101-1 and the individual electrode layer 101-2. That is, an electric field strength applied to t interlayer insulating film 110 (insulating protective film) is set in a range that does not cause dielectric breakdown of the interlayer insulating film 110. Considering surface properties and pinholes of the base of the interlayer insulating film 110, the film thickness of the interlayer insulating film 110 is preferably 200 nm or more, and more preferably 500 nm or more.

After film-forming the interlayer insulating film 110, a connection hole 111 that connects the individual electrode layer 101-2 and a lead wire 108 is formed by a photolithographic etching (see FIG. 6C). When the common electrode layer 101-1 is connected to another lead wire, a connection hole is formed in the interlayer insulating film 110 in the same manner as the connection hole 111. Then, as illustrated in FIG. 6D, lead wire 108 is formed on the interlayer insulating film 110.

As a material of the lead wire 108, a metal electrode material composed of any one of an Ag alloy, Cu, Al, Au, Pt, and Ir is preferable. As a method for preparing the lead wire 108, sputtering or a spin coating is used, and then a desired pattern is obtained by photolithography etching or the like. The film thickness of the lead wire 108 is preferably from 0.1 to 20 μm and is more preferably from 0.2 to 10 μm. If the film thickness of the lead wire 108 is smaller than the above-described range (from 0.1 to 20 μm), resistance of the lead wire 108 increases so that a sufficient current may not flow through the individual electrode layer 101-2, and the head 10 may not stably discharge a liquid.

If the film thickness of the lead wire 108 is larger than the above-described range (from 0.1 to 20 μm), time for processing (preparing) the lead wire 108 increases. The contact resistance of the lead wire 108 with the individual electrode layer 101-2 in the connection hole 111 is preferably 1Ω or less and is more preferably 0.5Ω or less. The contact resistance of the lead wire 108 with the common electrode layer 101-1 in a connection hole is preferably 10Ω or less and is more preferably 5Ω or less.

If the contact resistance of the lead wire 108 with the individual electrode layer 101-2 is larger than the above described range, the lead wire 108 cannot supply a sufficient current to the piezoelectric element 101, and thus a problem occurs when the head 10 discharges the ink.

Further, as described below, the lead wire 108 is also formed in a bonding region of the holding substrate 200. As illustrated in FIG. 4, a layer structure identical to a layer structure of a bonding region of the lead wire 108 side is formed in a bonding region 109 so that the holding substrate 200 has a uniform height in the bonding region in the present embodiment. The bonding region 109 is a region at which the holding substrate 200 is bonded. The bonding region 109 is disposed on a side (on the common channel 202 side) opposite to the lead wire 108 with the piezoelectric element 101 interposed between the lead wire 108 and the bonding region 109. Thus, the lead wire 108 can be reliably bonded to the holding substrate 200.

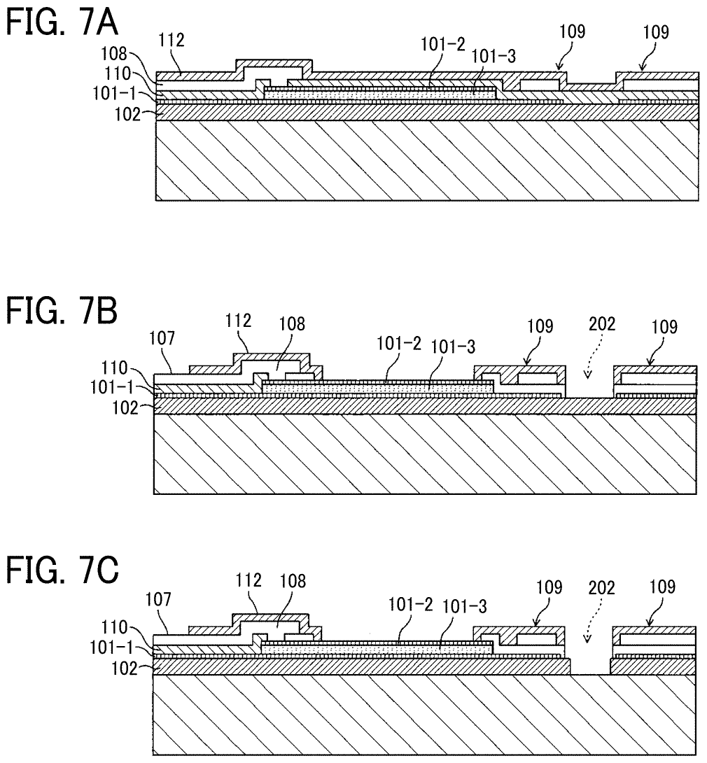

Next, as illustrated in FIG. 7A, a passivation film 112 functioning as a protection layer of the lead wire 108 is formed on the lead wire 108. The passivation film 112 enable a use of inexpensive Al or an alloy material containing Al as a main component as the material of the lead wire 108. Thus, the head 10 of the present embodiment can be manufactured at low cost and can reliably discharge the liquid. As the material of the passivation film 112, any inorganic material or organic material can be used. However, a material with low moisture permeability may be used for the material of the passivation film 112. Examples of the inorganic material include oxides, nitrides, carbides, and the like, and examples of the organic material include polyimide, acrylic resin, urethane resin, and the like. However, the passivation film 112 made of the organic material has to be made thick, and thus is not suitable for patterning as described below.

Thus, the inorganic material is preferably used for the passivation film 112 because the passivation film 112 made of inorganic material can protect the lead wire 108 with a thin film. Particularly, it is preferable to form the passivation film 112 made of Si₃N₄ on the lead wire 108 made of Al that is a technology widely used in semiconductor devices. The film thickness of the passivation film 112 is preferably 200 nm or more and is more preferably 500 nm or more. When the film thickness of the passivation film 112 is small, the passivation film 112 cannot exhibit sufficient passivation function. Thus, disconnection due to corrosion of the lead wire 108 occurs, and the reliability of the head 10 is lowered.

As illustrated in FIG. 7B. a portion of the passivation film 112 disposed on the piezoelectric element 101 and a portion overlapping a vicinity of the piezoelectric element 101 are preferably removed so that the passivation film 112 does not hamper displacement (deformation) of the diaphragm 102. Thus, an inkjet head (liquid discharge head 10) of the present embodiment can efficiently and reliably discharge the liquid.

More specifically, as illustrated in FIG. 7B, a photolithography or a dry etching is used to remove an end portion of the lead wire 108 serving as an individual electrode pad 107 connected to the drive IC 120, a part of top surface of the piezoelectric element 101, and the passivation film 112 and the interlayer insulating film 110 at a part of the common channel 202. Then, as illustrated in FIG. 7C, a portion of the diaphragm 102 communicating with the common channel 202 and the common chamber 106 is removed by the photolithographic etching.

An individual electrode pad 107 made of a bump electrode for connecting the drive IC 120 is formed at an end portion of the lead wire 108 (see FIGS. 7B and 7C). Examples of methods of forming the individual electrode pad 107 include electrolytic plating, electroless plating, stud bumping, and the like. Examples of a material of the individual electrode pad 107 include Au, Ag, Cu, Ni, solder, and the like.

As a method for connecting the drive IC 120 to the individual electrode pad 107, for example, Anisotropic Conductive Film (ACF) bonding using Flexible Printed Circuits (FPC), solder bonding, wire bonding, or flip-chip bonding directly connected to an output terminal of the drive IC 120 can be selectively used. However, the wire bonding and the flip chip bonding are advantageous in terms of cost compared with the ACF bonding because a parts cost of FPC used in the ACF bonding is expensive.

Further, the wire bonding is slower in a tact time compared with the flip chip bonding, and thus productivity of the wire bonding is poor, and the wire bonding is also disadvantageous for narrowing pitch. Therefore, the drive IC 120 is connected to the individual electrode pad 107 by flip chip bonding, and the drive IC 120 is mounted on the individual electrode pad 107 by flip chip mounting in the present embodiment.

Next, as illustrated in FIG. 8A, a leg portion 200a of the holding substrate 200 and the bonding region 109 are bonded with an adhesive 114. The leg portion 200a is formed in the holding substrate 200 that has a recess 203 at a position corresponding to a diaphragm displacement region 113. The bonding region 109 is disposed over the actuator substrate 100. The actuator substrate 100 may not ensure a sufficient rigidity if the actuator substrate 100 has a thickness of about 20 to 100 μm for forming the pressure chamber 104, for example.

Thus, the holding substrate 200 is adhered to the actuator substrate 100 to ensure rigidity. Therefore, the holding substrate 200 is preferably made of a high-rigidity material such as silicon rather than a low-rigidity material such as resin. A material having a thermal expansion coefficient close to a thermal expansion coefficient of the actuator substrate 100 is selected for the holding substrate 200 to prevent warping of the actuator substrate 100. Therefore, the actuator substrate 100 is preferably made of a ceramic material such as glass, silicon, SiO₂, ZrO₂, Al₂O₃, and the like.

The recess 203 is formed in the holding substrate 200 at a position corresponding to the diaphragm displacement region 113 facing the piezoelectric element 101. A space for displacement (deformation) of the piezoelectric element 101 is secured by the recess 203.

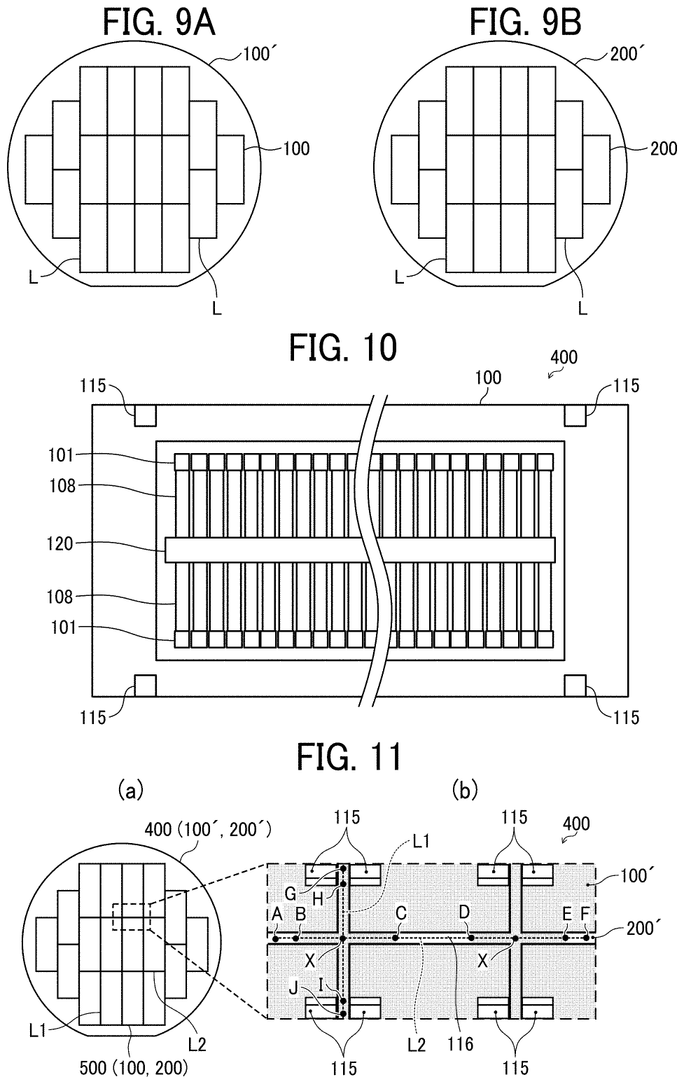

As illustrated in FIGS. 9A and 9B, and FIG. 10, the recesses 203 of the holding substrate 200 are partitioned so that the recesses 203 respectively correspond to the piezoelectric elements 101. Thus, the actuator substrate 100 having a thin plate-thickness can ensure sufficient rigidity. Thus, mutual interference between adjacent pressure chambers 104 may be reduced occurred when each piezoelectric elements 101 is driven.

Further, as illustrated in FIGS. 9A and 9B, and FIG. 10, the recesses 203 of the holding substrate 200 is partitioned for each piezoelectric element 101. Thus, a high processing accuracy is needed to increase a density of the piezoelectric element 101. For example, to obtain the head 10 capable of recording an image of 300 dpi, a width T1 of the partition wall that partitions the recess 203 of the holding substrate 200 is preferably from 5 to 20 μm.

Next, as illustrated in FIG. 8B, the partition walls 103 other than the pressure chamber 104, the common chamber 106, and the fluid restrictors 105 are covered with a resist by photolithography. Next, anisotropic wet etching is performed using an alkali solution (for example, a potassium hydroxide (KOH) solution or a tetramethylammonium hydroxide (TMHA) solution) to form the pressure chamber 104, the common chamber 106, and the fluid restrictor 105. In addition to anisotropic etching using an alkaline solution, the pressure chambers 104, the common chamber 106, and the fluid restrictors 105 may be formed by, for example, dry etching using an Inductive Coupled Plasma (ICP) etcher.

Next, as illustrated in FIG. 8C, a protective layer is formed over the actuator substrate 100 and the holding substrate 200. This protective layer is, for example, a liquid contact film 140 for providing wettability with ink. The liquid contact film 140 is preferably made of a dense film of a metal oxide, and preferably contains at least one of tantalum or zirconium.

The ALD or the sputtering may be used as a method for forming the protective layer (liquid contact film 140), for example. In the ALD, metal atoms and oxygen atoms as a liquid contact film material (protective layer material) are alternately film-formed to form an oxide film. Then, as illustrated in FIG. 8D, a nozzle substrate 300 is bonded to the partition walls 103. The nozzle substrate 300 has nozzles 301 opened at positions corresponding to the pressure chambers 104, respectively

The above description is an example of a method of manufacturing the head 10, and the present embodiment is not limited to the embodiment described above.

Following describes a laminated substrate used for manufacturing the electromechanical transducer substrate of the head 10

FIG. 9A is a schematic plan view of a first silicon substrate 100′ as a first mother substrate including the actuator substrate 100 as a first substrate.

FIG. 9B is a schematic plan view of a second silicon substrate 200′ as a second mother substrate including the holding substrate 200 as a second substrate.

FIG. 10 is an enlarged schematic plan view of one actuator substrate 100 formed on the first silicon substrate 100′.

Both the first silicon substrate 100′ and the second silicon substrate 200′ are 6-inch silicon substrates. As illustrated in FIG. 9A, multiple chips (actuator substrates 100) are formed on the first silicon substrate 100′ in this embodiment. As described above, the chips (actuator substrates 100) are laminated layer structures formed by sequentially film-forming multiple films.

Further, contact terminals 115 are formed (provided) at substrate ends near four corners of the chip (actuator substrate 100) as illustrated in FIG. 10. The contact terminals 115 contact external terminals. More specifically, two contact terminals 115 are formed (provided) at each end of the chips (actuator substrates 100) in a short side direction (vertical direction in FIG. 10) as illustrated in FIG. 10. The short side direction is orthogonal to a longitudinal direction (horizontal direction in FIG. 10).

Thus, the bonded silicon substrate 400 (the first silicon substrate 100′ and the second silicon substrate 200′) includes four contact terminals 115 at four corners of the actuator substrate 100.

On the other hand, the holding substrate 200 is formed on the second silicon substrate 200′ at positions corresponding to the chips (actuator substrates 100) on the first silicon substrate 100′ as illustrated in FIGS. 9A and 9B. In the present embodiment, the first silicon substrate 100′ coated with an adhesive and the second silicon substrate 200′ are bonded together to form a bonded silicon substrate 400 (see FIG. 10) as a bonded substrate, for example. Then, a dicing step (separation step) is performed.

The dicing step divides the bonded silicon substrate 400 (the first silicon substrate 100′ and the second silicon substrate 200′) along a predetermined dividing line “L” indicated in FIGS. 9A and 9B. As a result, individual bonded substrates 500, in each of which the actuator substrate 100 and the holding substrate 200 are bonded, are separated from the bonded silicon substrate 400 (the first silicon substrate 100′ and the second silicon substrate 200′).

In the dicing step, the bonded silicon substrate 400 (the first silicon substrate 100′ and the second silicon substrate 200′) has to be appropriately divided along the dividing line L without a division failure such as crack. Therefore, members existing on the dividing lines L of the bonded silicon substrate 400 (the first silicon substrate 100′ and the second silicon substrate 200′) are removed.

Examples of the members existing on the dividing lines L include substrate materials of the first silicon substrate 100′ and the second silicon substrate 200′, a laminated structure formed on the materials of the first silicon substrate 100′ and the second silicon substrate 200′, the adhesive 114 for bonding the first silicon substrate 100′ and the second silicon substrate 200′ described above to form the bonded silicon substrate 400, and the like. Therefore, the thickness of the bonded silicon substrate 400 (the first silicon substrate 100′ and the second silicon substrate 200′) on the dividing line L is previously made thinner than other portions (portions other than the dividing line L).

More specifically, at least a part of the laminated structures on the dividing lines L is removed in etching or the like for forming various laminated structures on the first silicon substrate 100′ and the second silicon substrate 200′.

A stealth dicing is adopted to modify the substrate material (silicon substrate) by laser to make the substrate material brittle for the substrate materials of the first silicon substrate 100′ and the second silicon substrate 200′ on the dividing line L. In the dicing step of the present embodiment, the bonded silicon substrate 400 (the first silicon substrate 100′ and the second silicon substrate 200′) are divided along the dividing lines L by a method such as an expand separation dicing tape.

Further, a cutoff step that cuts off a part of the first silicon substrate 100′ on the dividing line L is performed to further appropriately divide the bonded silicon substrate 400 (the first silicon substrate 100′ and the second silicon substrate 200′) in the present embodiment. Specifically, a central portion (between “C” and “D” in FIG. 11(b)) of a short side L2 of a rectangular chip (actuator substrate 100) among the dividing lines L of the first silicon substrate 100′ is cut off as illustrated in an enlarged plan view of FIG. 11(b), for example.

The cutoff step cuts off a central portion (between “C” and “D” in FIG. 11(b)) in a longitudinal direction (horizontal direction in FIG. 11(b)) of the first substrate (100) in (along) the dividing line (L) to form a cutoff portion 116. The cutoff off portion 116 disposed at a center in a short side direction (vertical direction in FIG. 11(b)) of the bonded silicon substrate 400.

In this cutoff step, a resist layer patterned by exposure and development is formed on one surface of the first silicon substrate 100′ opposite to another surface of the first silicon substrate 100′ facing the second silicon substrate 200′, for example. Further, this resist layer is etched as mask, and then the resist layer is removed to perform the cutoff step.

As described above, a part of the chip short side L2 on the dividing line L of the first silicon substrate 100′ is removed to reduce a division failure of the chip short side L2. Thus, good separability at a time of expansion of the expand separation dicing tape can be obtained. The central portion of the chip short side L2 on the dividing line L of the first silicon substrate 100′ is cut off in the present embodiment. However, an end portion of the chip short side L2 on the dividing line L may be cut off, or a part of the central portion or the end portion of the chip long side L1 on the dividing line L may be cut off.

Members existing on the dividing lines L of the bonded silicon substrate 400 (the first silicon substrate 100′ and the second silicon substrate 200′) are removed to reduce the thickness of the bonded silicon substrate 400 on the dividing lines L to be thinner than the thickness of other portions of the bonded silicon substrate 400.

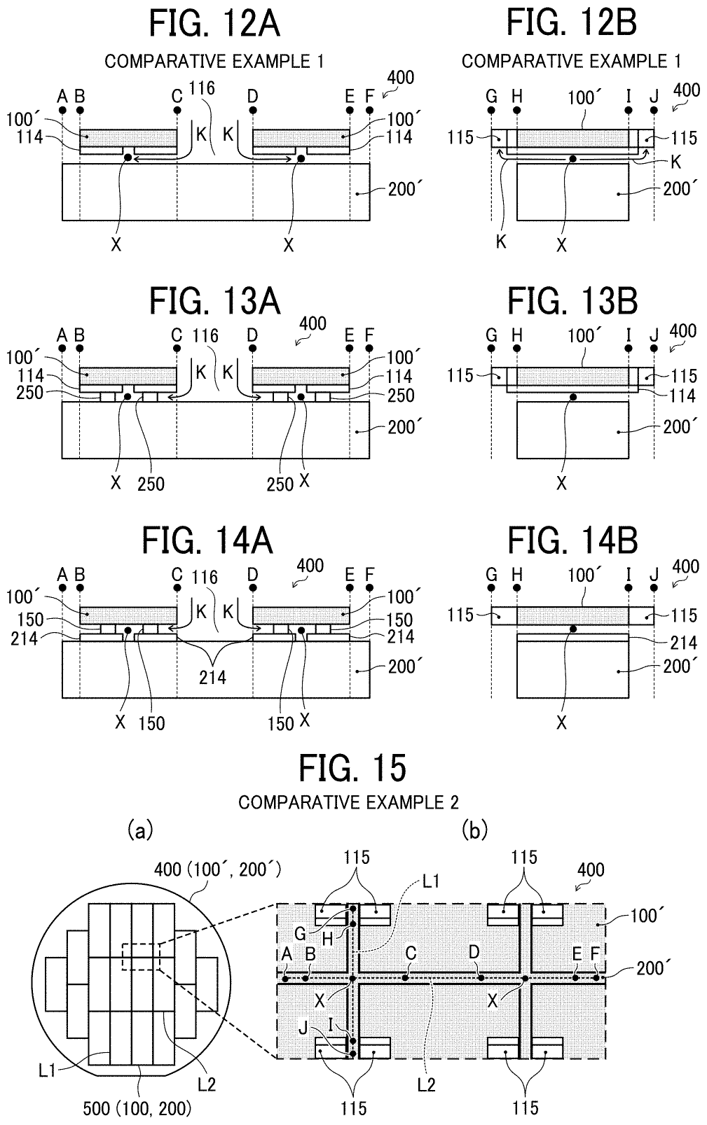

Then, a gap is formed between the first silicon substrate 100′ and the second silicon substrate 200′ on the dividing line L as in Comparative Example 1 illustrated in FIGS. 12A and 12B. The gap serves as a communication path as described below.

As illustrated in FIG. 8C in the present embodiment, the liquid contact film forming process is performed after performing the above-described cutoff step of cutting off the central portion of the chip short side L2 on the dividing line L of the first silicon substrate 100′. The liquid contact film forming process applies the liquid contact film material on the actuator substrate 100 and the holding substrate 200 to form the liquid contact film 140 (protective layer) on the actuator substrate 100 and the holding substrate 200.

Therefore, the liquid contact film material applied during the liquid contact film forming step enters a gap between the first silicon substrate 100′ and the second silicon substrate 200′ from a cutoff portion 116 of the first silicon substrate 100′ (a portion between “C” and “D” in FIG. 12A) as indicated by arrow “K” in FIGS. 12A and 12B. The cutoff portion 116 is an “exposed portion” at which the second silicon substrate 200′ is exposed through the first silicon substrate 100′.

Then, the liquid contact film material entering the gap advances along the gap on the dividing line L, and passes through an intersection “X” (see FIG. 11(b)) between the chip long side L1 and the chip short side L2 of the chip (actuator substrate 100), for example.

Then, the liquid contact film material proceeds to the contact terminal 115 exposed to the chip long side L1 on the dividing line L. As a result, the liquid-contact film material may adhere to the contact terminal 115 to cause contact failure of the contact terminal 115.

FIG. 13A is a cross-sectional view of the bonded silicon substrate 400 (the first silicon substrate 100′ and the second silicon substrate 200′) according to the present embodiment along the chip short side L2 on the dividing line L.

FIG. 13B is a cross-sectional view of the bonded silicon substrate 400 (the first silicon substrate 100′ and the second silicon substrate 200′) according to the present embodiment along the chip long side L1 on the dividing line L.

A structure 250 is formed in a communication path (gap) in which the contact terminal 115 communicates with the cutoff portion 116 of the first silicon substrate 100′ through the gap between the first silicon substrate 100′ and the second silicon substrate 200′ on the dividing line L in the present embodiment. The structure 250 prevents a passage of the liquid contact film material through the communication path. This process for forming the structure 250 is also referred to as a “structure forming step” below.

This structure 250 can be formed of the same material as constituent parts formed on the holding substrate 200 at positions other than the dividing lines L, for example. Examples of the material of the structure 250 include a patterning material, an insulating film material, or the like. In the above case, the structure forming step is performed in a forming step of the constituent parts formed on the holding substrate 200 at positions other than the division lines L. Thus, the structure 250 is formed together with the constituent parts.

Such the structure 250 is formed to block the liquid contact film material that enters from the cutoff portion 116 (a portion between “C” and “D” in FIG. 13A) of the first silicon substrate 100′ so that the liquid contact film material cannot reach the contact terminal 115 by the structure 250. As a result, the structure 250 can prevent the liquid contact film material from contacting with the contact terminal 115, thereby reduce occurrence of the contact failure.

In addition, this structure 250 continues to exist on the chip short side L2 of each chip after the dicing step (separating step). Each chip includes each bonded silicon substrate 400 (the first silicon substrate 100′ and the second silicon substrate 200′) in which the actuator substrate 100 and the holding substrate 200 are bonded As a result, the rigidity of the substrate on the dividing line L, which is thinner than other portions, can be reinforced by the structure 250.

A length of the structure 250 along the dividing line L (chip short side L2 in this embodiment) is preferably in a range from 10 to 100 μm (10 μm or more and 100 μm or less). Hereinafter, the length of the structure 250 along the dividing line L is referred to as a “width of the structure 250”. If the width of the structure 250 is less than 10 μm, the structure 250 insufficiently functions. to prevent the passage of the liquid contact film material.

Further, if the width of the structure 250 is less than 10 μm, the structure 250 may not sufficiently reinforce the rigidity of the chips such as the individual bonded substrates 500 (the actuator substrate 100 and the holding substrate 200 bonded with each other). If the width of the structure 250 exceeds 100 μm, the structure 250 may prohibit division of the bonded silicon substrate 400 during the expansion of the expand separation dicing tape in the dicing step. The width of the structure 250 is set to 50 μm in the present embodiment.

Further, the structure 250 is formed together with the constituent parts formed on the second silicon substrate 200′ and bonded to the first silicon substrate 100′ with the adhesive 114 applied to the first silicon substrate 100′ in the present embodiment. For example, a structure 250 is formed of the same material as the constituent parts formed on the first silicon substrate 100′ except a portion on the dividing lines L as illustrated in FIGS. 14A and 14B.

Examples of the material of the structure 250 include a patterning material, an insulating film material, or the like. the structure 250 may be bonded to the second silicon substrate 200′ with the adhesive 214 applied to the second silicon substrate 200′. In either case, the adhesive may be applied to the first silicon substrate 100′. However, it is difficult to apply the adhesive to the first silicon substrate 100′. since a complex pattern is formed (arranged) on the first silicon substrate 100′. In such a case, an adhesive is preferably applied to the second silicon substrate 200′.

Next, results of a comparative experiment between the present embodiment and Comparative Examples 1 and 2 are described below.

As illustrated in FIGS. 12A and 12B, Comparative Example 1 differs from the bonded silicon substrate 400 (the first silicon substrate 100′ and the second silicon substrate 200′) of the present embodiment only in that the structure 250 is not formed. That is, the structure forming step is not performed in Comparative Example 1.

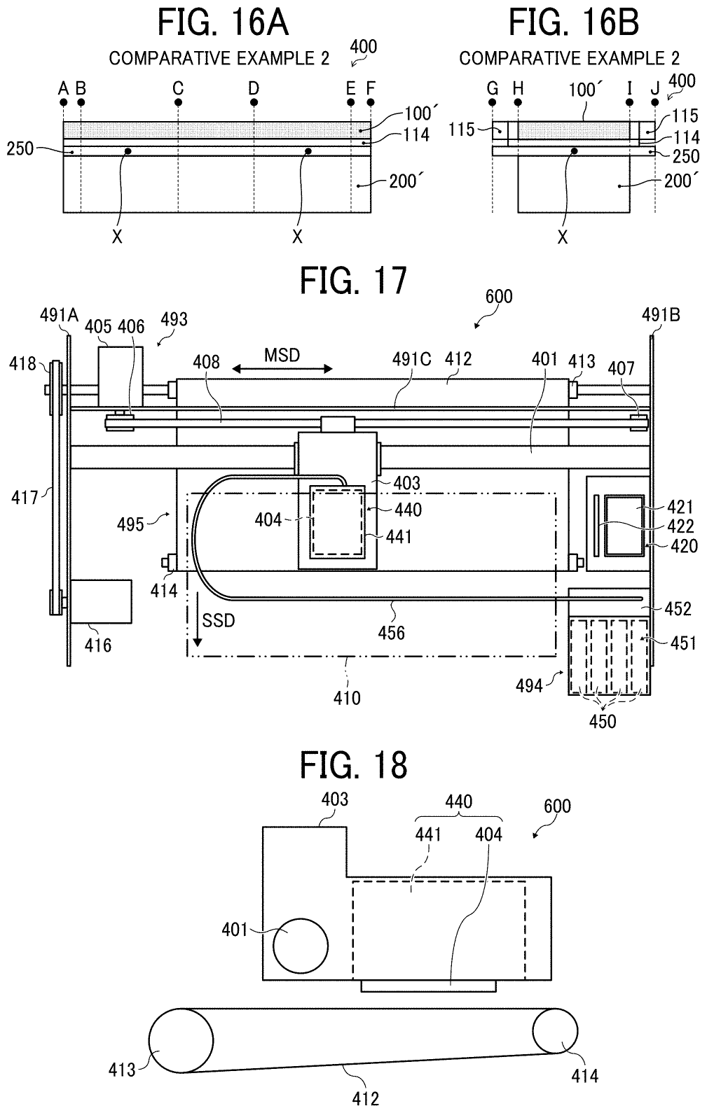

As illustrated in FIGS. 15 and FIGS. 16A and 16B, Comparative Example 2 is different from the bonded silicon substrate 400 (the first silicon substrate 100′ and the second silicon substrate 200′) of the present embodiment in that a part of the first silicon substrate 100′ on the dividing line L is not cut off. That is, the cutoff step is not performed in Comparative Example 2. Comparative Example 2 is also different in that the structure 250 formed on the dividing line L is formed over the entire dividing line L.

In this comparative experiment, stealth dicing was performed on the bonded silicon substrate 400 (the first silicon substrate 100′ and the second silicon substrate 200′) of the present embodiment and Comparative Examples 1 and 2. The separability (dividing ability) was confirmed, and contact failure (electrical inspection) of the contact terminal 115 was performed. The results are illustrated in Table 1.

TABLE 1

| | | COMPARATIVE | COMPARATIVE |
|---|---|---|---|
| | EMBODIMENT | EXAMPLE 1 | EXAMPLE 2 |
| NON-DEFECTIVE | 100% | 100% | 77% |
| RATE IN | | | |
| SEPARABILITY | | | |
| NON-DEFECTIVE | 100% | 83% | 100% |
| RATE IN | | | |
| ELECTRICAL | | | |
| INSPECTION | | | |

In the present embodiment, the non-defective ratio of the separability was 100%, and the non-defective ratio of the contact failure (electrical inspection) of the contact terminal 115 was also 100%. With respect to the separability, a division failure such as a crack did not occur since the cutoff step of cutting off a part of the first silicon substrate 100′ on the dividing line L was performed.

Also, since the width of the structure 250 formed on the dividing line L was as narrow as 50 μm, there was no influence on the separability (dividing ability). The existence of the structure 250 prevents the liquid contact film material entering from the cutoff portion 116 of the first silicon substrate 100′ on the dividing line L from reaching the contact terminal 115 during the liquid contact film forming step. Thus, contact failure of the contact terminal 115 was not confirmed.

On the other hand, the non-defective rate of the separability was 100% in Comparative Example 1. However, a non-defective rate of contact failure (electrical inspection) of the contact terminal 115 was 83%. With respect to the separability, a division failure such as a crack or a crack did not occur since the cutoff step of cutting off a part of the first silicon substrate 100′ on the dividing line L was performed as in the present embodiment.

On the other hand, regarding contact failure (electrical inspection) of the contact terminal 115, the liquid contact film material entering from the cutoff portion 116 of the first silicon substrate 100′ on the dividing line L reaches the contact terminal 115 during the liquid contact film forming process, and contact failure of the contact terminal 115 may occur since the structure 250 does not exist in Comparative Example 2.

In Comparative Example 2, the non-defective rate in the separability was 77%, and the non-defective rate in the contact failure (electrical inspection) of the contact terminal 115 was 100%. With respect to the separability (dividing ability), a division failure such as a crack may occur since the cutoff step that cuts off a part of the first silicon substrate 100′ on the dividing line L is not performed in Comparative Example 2.

In particular, cracks were sometimes generated along the adhesive 114 in a portion where the adhesive 114 remained. On the other hand, regarding the contact failure (electrical inspection) of the contact terminal 115, there was no cutoff portion 116 in the first silicon substrate 100′ on the dividing line L in Comparative Example 2. Thus, the liquid contact film material could not enter during the contact liquid film forming step so that contact failure of the contact terminal 115 did not occur.

Although the chip of the present embodiment is described by taking a chip having a rectangular shape as an example, the shape of the chip is not particularly limited.

FIGS. 17 and 18 illustrate an example of a printer 600 as a liquid discharge apparatus according to an embodiment of the present disclosure.

FIG. 17 is a plan view of a portion of the printer 600. FIG. 18 is a side view of a portion of the printer 600 of FIG. 17.

The printer 600 as a liquid discharge apparatus is a serial-type apparatus, and the carriage 403 reciprocally moves in a main scanning direction indicated by arrow “MSD” by a main scan moving unit 493. The main scan moving unit 493 includes a guide 401, a main scan motor 405, a timing belt 408, and the like. The guide 401 is bridged between a left-side plate 491A and a right-side plate 491B to movably hold the carriage 403. The main scan motor 405 reciprocally moves the carriage 403 in the main scanning direction MSD via the timing belt 408 bridged between a drive pulley 406 and a driven pulley 407.

The carriage 403 mounts the liquid discharge device 440. The head 404 (liquid discharge head) according to the above-described embodiments of the present disclosure and the head tank 441 form the liquid discharge device 440 as a single unit. The head 404 of the liquid discharge device 440 discharges liquid of each color, for example, yellow (Y), cyan (C), magenta (M), and black (K). The head 404 includes a nozzle array including multiple nozzles arrayed in row in a sub-scanning direction indicated by arrow “SSD” in FIG. 17. The head 404 is mounted to the carriage 403 so that ink droplets are discharged downward. The sub-scanning direction is orthogonal to the main scanning direction MSD.

The liquid stored in liquid cartridges 450 are supplied to the head tank 441 by a supply unit 494 to supply the liquid stored outside the head 404 to the head 404.

The supply unit 494 includes a cartridge holder 451 serving as a filling part to mount the liquid cartridges 450, a tube 456, a liquid feeder 452 including a liquid feed pump, and the like. The liquid cartridge 450 is detachably attached to the cartridge holder 451. The liquid is fed from the liquid cartridge 450 to the head tank 441 by the liquid feeder 452 via the tube 456.

The printer 600 includes a conveyor 495 to convey a sheet 410. The conveyor 495 includes a conveyance belt 412 as a conveyor and a sub scan motor 416 to drive the conveyance belt 412.

The conveyance belt 412 attracts the sheet 410 and conveys the sheet 410 at a position facing the head 404. The conveyance belt 412 is an endless belt stretched between a conveyance roller 413 and a tension roller 414. Attraction of the sheet 410 to the conveyance belt 412 may be applied by electrostatic adsorption, air suction, or the like.

The conveyance belt 412 rotates in the sub scanning direction SSD as the conveyance roller 413 is rotationally driven by the sub scan motor 416 via the timing belt 417 and the timing pulley 418.

At one side in the main scanning direction MSD of the carriage 403, a maintenance unit 420 to maintain the head 404 in good condition is disposed on a lateral side of the conveyance belt 412.

The maintenance unit 420 includes, for example, a cap 421 to cap a nozzle surface of the head 404, a wiper 422 to wipe the nozzle surface, and the like. The nozzle surface is an outer surface of the nozzle substrate 300 (see FIG. 1) on which the nozzles 301 are formed.

The main scan moving unit 493, the supply unit 494, the maintenance unit 420, and the conveyor 495 are mounted to a housing that includes a left-side plate 491A, a right-side plate 491B, and a rear-side plate 491C.

In the printer 600 thus configured, the sheet 410 is conveyed on and attracted to the conveyance belt 412 and is conveyed in the sub scanning direction SSD by the cyclic rotation of the conveyance belt 412.

The head 404 is driven in response to image signals while the carriage 403 moves in the main scanning direction MSD, to discharge a liquid to the sheet 410 stopped, thus forming an image on the sheet 410.

As described above, the printer 600 as the liquid discharge apparatus includes the head 404 according to the above-described embodiments of the present disclosure, thus allowing stable formation of high quality images.

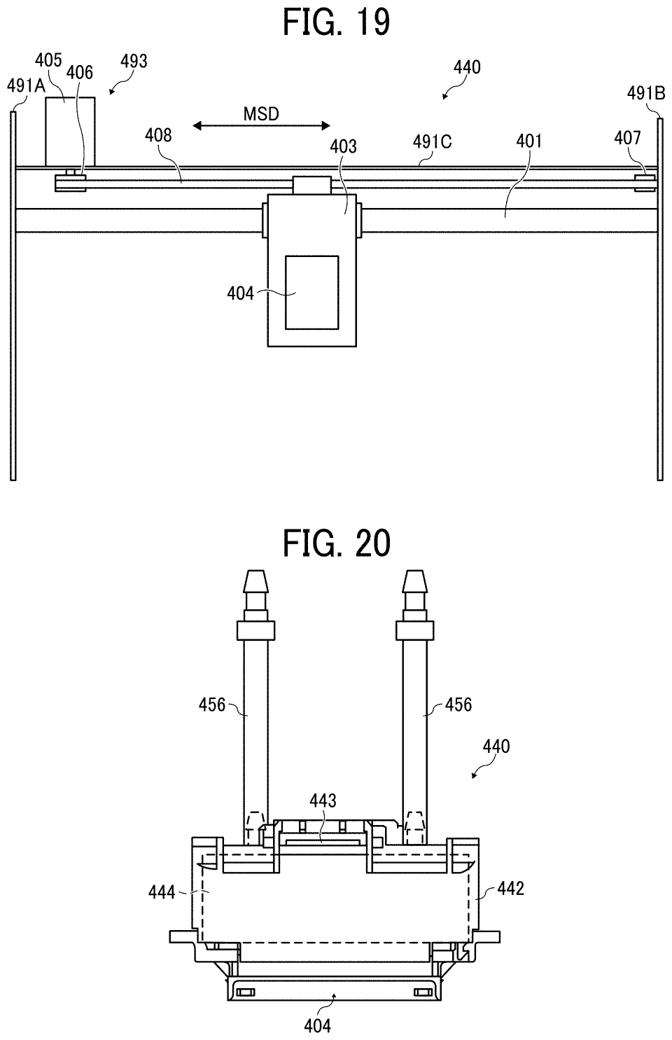

Next, the liquid discharge device 440 according to a still another embodiment of the present disclosure is described with reference to FIG. 19.

FIG. 19 is a plan view of a portion of the liquid discharge device 440 according to the still another embodiment of the present disclosure.

The liquid discharge device 440 includes a housing, the main scan moving unit 493, the carriage 403, and the head 404 among components of the printer 600 as the liquid discharge apparatus. The left-side plate 491A, the right-side plate 491B, and the rear-side plate 491C configure the housing.

The liquid discharge device 440 may be configured to further attach at least one of the above-described maintenance unit 420 and the supply unit 494 to, for example, the right-side plate 491B of the liquid discharge device 440.

Next, still another example of the liquid discharge device 440 according to the present embodiment is described with reference to FIG. 20. FIG. 20 is a schematic front view of still another example of the liquid discharge device 440.

The liquid discharge device 440 includes the head 404 to which a channel part 444 is mounted and a tube 456 connected to the channel part 444.

Further, the channel part 444 is disposed inside a cover 442. Instead of the channel part 444, the liquid discharge device 440 may include the head tank 441. A connector 443 electrically connected with the head 404 is provided on an upper part of the channel part 444.

In the above-described embodiments, the “liquid discharge apparatus” includes the head or the liquid discharge device and drives the head to discharge a liquid. The liquid discharge apparatus may be, for example, an apparatus capable of discharging liquid to a material onto which liquid can adhere and an apparatus to discharge liquid toward gas or into liquid.

The “liquid discharge apparatus” may include devices to feed, convey, and eject the material on which liquid can adhere. The liquid discharge apparatus may further include a pretreatment apparatus to coat a treatment liquid onto the material, and a post-treatment apparatus to coat a treatment liquid onto the material, onto which the liquid has been discharged.

The “liquid discharge apparatus” may be, for example, an image forming apparatus to form an image on a sheet by discharging ink, or a three-dimensional fabrication apparatus to discharge a fabrication liquid to a powder layer in which powder material is formed in layers to form a three-dimensional fabrication object.

The “liquid discharge apparatus” is not limited to an apparatus to discharge liquid to visualize meaningful images, such as letters or figures. For example, the liquid discharge apparatus may be an apparatus to form arbitrary images, such as arbitrary patterns, or fabricate three-dimensional images.

The above-described term “material on which liquid can adhere” represents a material on which liquid is at least temporarily adhered, a material on which liquid is adhered and fixed, or a material into which liquid is adhered to permeate. Examples of the “material on which liquid can adhere” include recording media, such as paper sheet, recording paper, recording sheet of paper, film, and cloth, electronic component, such as electronic substrate and piezoelectric element, and media, such as powder layer, organ model, and testing cell. The “material on which liquid can adhere” includes any material on which liquid adheres unless particularly limited.

Examples of the “material on which liquid can adhere” include any materials on which liquid can adhere even temporarily, such as paper, thread, fiber, fabric, leather, metal, plastic, glass, wood, ceramic, construction materials (e.g., wallpaper or floor material), and cloth textile.

Examples of the “liquid” include ink, treatment liquid, DNA sample, resist, pattern material, binder, fabrication liquid, and solution or liquid dispersion containing amino acid, protein, or calcium.

The “liquid discharge apparatus” may be an apparatus to relatively move the head and a material on which liquid can adhere. However, the liquid discharge apparatus is not limited to such an apparatus. For example, the liquid discharge apparatus may be a serial head apparatus that moves the head or a line head apparatus that does not move the head.

Examples of the “liquid discharge apparatus” further include a treatment liquid coating apparatus to discharge a treatment liquid to a sheet surface to coat the sheet with the treatment liquid to reform the sheet surface and an injection granulation apparatus to discharge a composition liquid including a raw material dispersed in a solution from a nozzle to mold particles of the raw material.

The “liquid discharge device” is an assembly of parts relating to liquid discharge. The term “liquid discharge device” represents a structure including the head and a functional part(s) or mechanism combined to the head to form a single unit.

For example, the “liquid discharge device” includes a combination of the head with at least one of a head tank, a carriage, a supply unit, a maintenance unit, and a main scan moving unit to form a single unit.

Here, examples of the “single unit” include a combination in which the head and a functional part(s) or unit(s) are secured to each other through, e.g., fastening, bonding, or engaging, and a combination in which one of the head and a functional part(s) or unit(s) is movably held by another.

Further, the head, the functional parts, and the mechanism may be configured to be detachable from each other.

For example, as a liquid discharge device 440, there is a liquid discharge device in which the head 404 and the head tank 441 form a single unit, as in the liquid discharge device 440 illustrated in FIG. 18. Alternatively, the head and the head tank coupled (connected) with a tube or the like may form the liquid discharge device as a single unit. A unit including a filter may be added at a position between the head tank and the head of the liquid discharge device.

In another example, the head and the carriage may form the liquid discharge device as a single unit.

In still another example, the liquid discharge device includes the head movably held by a guide that forms part of a main scan moving unit, so that the head and the main scan moving unit form a single unit. Like the liquid discharge device 440 illustrated in FIG. 19, the head, the carriage, and the main scan moving unit may form the liquid discharge device as a single unit.

In still another example, a cap that forms a part of the maintenance unit may be secured to the carriage mounting the head so that the head, the carriage, and the maintenance unit form a single unit to form the liquid discharge device.

Like the liquid discharge device 440 illustrated in FIG. 20, the tube 456 is connected to the head 404 mounting the head tank 441 or the channel part 444 so that the head 404 and the supply unit 494 (see FIG. 17) form a single unit as the liquid discharge device 440.

The main scan moving unit may be a guide only. The supply unit may be a tube(s) only or a loading unit only.

The pressure generator used in the “liquid discharge head” is not limited to a particular-type of pressure generator. The pressure generator is not limited to the piezoelectric actuator (or a laminated piezoelectric element) described in the above-described embodiments, and may be, for example, a thermal actuator that employs an electrothermal transducer element, such as a thermal resistor, or an electrostatic actuator including a diaphragm and opposed electrodes.

The terms “image formation”, “recording”, “printing”, “image printing”, and “fabricating” used herein may be used synonymously with each other.

The above-described embodiments are limited examples, and the present disclosure includes, for example, the following aspects having advantageous effects.

[Aspect 1]

According to an aspect 1, a method for manufacturing a bonded substrate 500 includes bonding a first mother substrate (100′) including a first substrate (100) and a second mother substrate (200′) including a second substrate (200) to form a bonded mother substrate (400); cutting off a part of the first mother substrate (100′) along a dividing line L of the bonded mother substrate (400) to form a cutoff portion 116; dividing the bonded mother substrate (400) along the dividing line L; separating a bonded substrate 500 from the bonded mother substrate (400), the bonded substrate 500 including the first substrate (100) and the second substrate (200) bonded to the first substrate (100); forming a contact terminal 115 on an end portion of the first mother substrate (100′), the contact terminal 115 with an external terminal; forming a communication path between the first mother substrate (100′) and the second mother substrate (200′) along the dividing line L; forming a structure 250 in the communication path between the cutoff portion 116 and the contact terminal 115; and applying a protective layer material on the bonded mother substrate (400) from the cutoff portion 116 to form a protective layer (liquid contact film 140).

When the dicing step (separation step) is performed, the bonded mother substrate (400) has to be appropriately divided along the dividing line L without a division failure such as crack. The dicing step (separation step) separates a bonded substrate 500 from a bonded mother substrate (400).

Therefore, a thickness of a member existing on the dividing line L of the bonded mother substrate (400) is previously made thinner than other portions (portions other than the dividing line L) in many cases.

The member may be each member of the first mother substrate (100′) and the second mother substrate (200′), or an adhesive for bonding the first mother substrate (100′) and the second mother substrate (200′), and the like. As a result, a gap is formed between the first mother substrate (100′) and the second mother substrate (200′) on the dividing line L.

Here, a cutoff step to cut off a part of the first mother substrate (100′) on the dividing line L is performed to appropriately divide the bonded mother substrates (400). In this case, an application step that applies a protective layer material for forming a protective layer (liquid contact film 140) on the bonded mother substrate (400) is performed after the cutoff step. Then, the applied material can enter the gap between the first mother substrate (100′) and the second mother substrate (200′) on the dividing line L from the cutoff portion 116 of the first mother substrate (100′), and can adhere to components or the like exposed on the dividing line L.

Therefore, the contact terminal 115 is disposed at a position exposed to the dividing line L of the bonded mother substrate (400). The bonded substrate 500 includes the contact terminal 115 at a substrate end portion so that the protective layer material may adhere to the contact terminal 115. The contact terminal 115 is contactable with the external terminal. As a result, the protective layer material adheres to the contact terminals 115 to cause contact failure in the bonded substrate 500, for example.

Therefore, in the first aspect, a structure 250 is formed in the communication path in which the cutoff portion 116 of the first mother substrate and the contact terminal communicate with each other through a gap on the dividing line L in the structure formation step. The structure 250 prevents a passage of the protective layer material through the communication path. As a result, the aspect 1 can prevent the protective layer material from entering from the cutoff portion 116 of the first mother substrate (100′), passing through a communication path via the gap on the dividing line L, and contacting with the contact terminal 115. Thus, the first aspect can reduce occurrence of the contact failure.

[Aspect 2]

According to an aspect 2, the applying the protective layer material forms a liquid contact film 140 covering the first substrate (100) and the second substrate (200).

The aspect 2 can reduce occurrence of contact failure due to contact of the liquid contact film material with the contact terminal 115.

[Aspect 3]

According to an aspect 3, a length of the structure 250 along the dividing line L is in a range of 10 to 100 μm (10 μm or more and 100 μm or less).

If the length of the structure 250 is within the above range, it is possible to prevent the protective layer material from contacting with the contact terminals 115 while ensuring good separability when the bonded mother substrate (400) is divided along the dividing line L.

[Aspect 4]

According to an aspect 4, the cutting off cuts off a central portion in a longitudinal direction of the first substrate (100) in the dividing line L.

[Aspect 5]

According to an aspect 5, the forming the structure 250 forms the structure 250 together with constituent parts of the second substrate (200) at positions other than the dividing line L.

According to the aspect 5, the structure 250 can be formed together with the constituent parts during a forming step that forms the constituent parts on the second substrate (200) to simplify a manufacturing process and shorten a manufacturing time.

[Aspect 6]

According to an aspect 6, the forming the structure (250) forms the structure (250) together with constituent parts of the first substrate (100) at positions other than the dividing line (L).

According to the aspect 6, the structure 250 can be formed together with the constituent parts during a forming step that forms the constituent parts on the first substrate (100) to simplify a manufacturing process and shorten a manufacturing time.

[Aspect 7]

According to an aspect 7, a bonded substrate 500 formed by bonding a first substrate (for example, an actuator substrate 100) and a second substrate (for example, a holding substrate 200) includes a contact terminal 115 in contact with an external terminal at the end of the bonded substrate 500. The first substrate (100) and the second substrate (200) have a protective layer (for example, a liquid contact film 140) based on a protective layer material (for example, a liquid contact film material).

Apart of the first mother substrate (100′) has a cutoff portion 116 on a dividing line L for separating the bonded substrate 500 from the bonded mother substrates (400) formed by bonding a first mother substrate (for example, a first silicon substrate 100′) including the first substrate (100) and a second mother substrate (for example, a second silicon substrate 200′) including the second substrate (200). A structure 250 is provided in a communication path in which the cutoff portion 116 of the first substrate (100) and the contact terminal 115 communicate with each other via a gap between the first mother substrate (100′) and the second mother substrate (200′) on the dividing line L.

In the aspect 7, the structure 250 is formed in a communication path in which the cutoff portion 116 of the first mother substrate (100′) and the contact terminal 115 communicate with each other through a gap on the dividing line L. As a result, the bonded substrate 500 according to the aspect 7 can prevent the protective layer material from entering from the cutoff portion 116 of the first mother substrate (100′) during a manufacturing process, passing through the communication path via the gap on the dividing line L, and contacting with the contact terminal 115.

Thus, the aspect 7 can provide a bonded substrate 500 that can reduce contact failure at the contact terminals 115. Further, the bonded substrate 500 includes the structure 250 in a communication path passing through the gap on the dividing line L. As a result, the structure 250 can reinforce the rigidity of a part of the bonded substrate 500 on the dividing line L having reduced rigidity.

[Aspect 8]

According to an aspect 8, a bonded substrate 500 includes: a first substrate (100); a second substrate (200) bonded to the first substrate (100); a contact terminal 115 on an end portion of the first substrate (100) in a short side direction of the first substrate, the contact terminal contactable with an external terminal; a protective layer (liquid contact film 140) covering the first substrate (100) and the second substrate (200); a cutoff portion 116 in a part of the first substrate (100) along a dividing line L in a longitudinal direction of the bonded substrate 500, the cutoff portion configured to expose the second substrate in a plan view of the bonded substrate 500 viewed from the first substrate (100); and a structure 150 connecting the first substrate and the second substrate, the structure 150 disposed between the cutoff portion 116 and the contact terminal 115 in a longitudinal direction orthogonal to the short side direction.

In the aspect 8, the structure 250 is formed in a communication path in which the cutoff portion 116 of the first mother substrate 100′ and the contact terminal 115 communicate with each other through a gap on the dividing line L.

As a result, the bonded substrate 500 according to the aspect 8 can prevent the protective layer material from entering from the cutoff portion 116 of the first mother substrate 100′ during a manufacturing process, passing through the communication path via the gap on the dividing line L, and contacting with the contact terminal 115.

Thus, the aspect 8 can provide a bonded substrate 500 that can reduce contact failure at the contact terminals 115. Further, the bonded substrate 500 includes the structure 250 in a communication path passing through the gap on the dividing line L. As a result, the structure 250 can reinforce the rigidity of a part of the bonded substrate 500 on the dividing line L having reduced rigidity.

[Aspect 9]

An aspect 9 is a bonded substrate 500 includes: a first substrate (100); a second substrate (200) bonded to the first substrate (100); a contact terminal 115 on an end portion of the first substrate (100) in a short side direction of the first substrate, the contact terminal contactable with an external terminal; a protective layer (liquid contact film 140) covering the first substrate (100) and the second substrate (200); a cutoff portion 116 in a part of the second substrate (200) along a dividing line L in a longitudinal direction of the bonded substrate 500, the cutoff portion (116) configured to expose the first substrate (100) in a plan view of the bonded substrate 500 viewed from the second substrate (200); and a structure 150 connecting the first substrate and the second substrate, the structure 150 disposed between the cutoff portion and the contact terminal in a longitudinal direction orthogonal to the short side direction.

According to the aspect 9, the bonded substrate includes the structure 250 connecting the first substrate (100) and the second substrate (200) between a portion from an exposed portion (cutoff portion 116) of the first substrate (100) to an end portion in a short-side direction of the bonded substrate 500. As a result, the bonded substrate 500 can prevent the protective layer material from entering from the exposed portion (cutoff portion 116) of the first substrate (100) to the contact terminal 115 during the manufacturing process by the structure 250. Thus, the aspect 9 can provide the bonded substrate that can reduce contact failure at the contact terminals. Further, the bonded substrate having such a structure 250 can reinforce rigidity of the bonded substrate by the structure 250.

[Aspect 10]

According to an aspect 10, the protective layer (liquid contact film 140) is a liquid contact film covering the first substrate (100) and the second substrate (200).

According to the aspect 10, the bonded substrate 500 can reduce contact failure at contact terminals 115 by the liquid contact film material.

[Aspect 11]

According to an aspect 11, a length of the structure 250 along the dividing line L is in a range of 10 to 100 μm (10 μm or more and 100 μm or less).

If the length of the structure 250 is within the above range, the bonded substrate 500 can prevent the contact failure at the contact terminals 115 while sufficiently reinforcing the bonded substrate by the structure 250.

[Aspect 12]

According to an aspect 12, the structure 250 is formed together with constituent parts of the second substrate (200) at positions other than the dividing line L.

According to the aspect 12, the structure 250 can be formed together with the constituent parts during a forming step that forms the constituent parts on the second substrate (200) to simplify a manufacturing process and shorten a manufacturing time.

[Aspect 13]

According to an aspect 13, the cutoff portion 116 is at a central portion in a longitudinal direction of the first substrate (100) in the dividing line L.

[Aspect 14]

According to an aspect 14, a liquid discharge head includes the bonded substrate 500.

According to the aspect 14, the liquid discharge head 10 using an electromechanical conversion substrate has reduced contact failure at contact terminals 115 and reinforced rigidity.

[Aspect 15]

According to an aspect 15, a liquid discharge device includes the liquid discharge head.

According to the aspect 15, the liquid discharge device 440 using an electromechanical conversion substrate has reduced contact failure at contact terminals 115 and reinforced rigidity.

[Aspect 16]

According to an aspect 16, the liquid discharge device 440 includes at least one of a head tank 441 for storing liquid to be supplied to the liquid discharge head 10, a carriage 403 for mounting the liquid discharge head, a supply unit 494 for supplying liquid to the liquid discharge head, a maintenance unit 420 for maintaining and recovering the liquid discharge head, and a main scan moving unit 493 for moving the liquid discharge head in the main scanning direction is formed together with the liquid discharge head 10.

According to the aspect 16, the liquid discharge device 440 using an electromechanical conversion substrate has reduced contact failure at contact terminals 115 and reinforced rigidity.

[Aspect 17]

According to the aspect 17, the liquid discharge apparatus (printer 600) includes the liquid discharge head 10 that uses an electromechanical conversion substrate having reduced contact failure at contact terminals 115 and reinforced rigidity.

The bonded substrate 500 according to the present embodiment can reduce occurrence of contact failure of the contact terminal 115 when the bonded substrate 500 is manufactured. The bonded substrate 500 has a contact terminal 115 in contact with an external terminal at a substrate end portion of the bonded substrate 500.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

1. A method for manufacturing a bonded substrate, the method comprising:
bonding a first mother substrate including a first substrate and a second mother substrate including a second substrate to form a bonded mother substrate;
cutting off a part of the first mother substrate along a dividing line of the bonded mother substrate to form a cutoff portion;
dividing the bonded mother substrate along the dividing line;
separating a bonded substrate from the bonded mother substrate, the bonded substrate including the first substrate and the second substrate bonded to the first substrate;
forming a contact terminal on an end portion of the first mother substrate, the contact terminal contactable with an external terminal;
forming a communication path between the first mother substrate and the second mother substrate along the dividing line;
forming a structure in the communication path between the cutoff portion and the contact terminal; and
applying a protective layer material on the bonded mother substrate from the cutoff portion to form a protective layer.

2. The method according to claim 1,
wherein the applying the protective layer material includes forming a liquid contact film that covers the first substrate and the second substrate.

3. The method according to claim 1,
wherein a length of the structure along the dividing line is in a range from 10 to 100 μm.

4. The method according to claim 1,
wherein the cutting off includes cutting off a central portion in a longitudinal direction of the first substrate in the dividing line.

5. The method according to claim 1,
wherein the forming the structure includes forming the structure together with constituent parts of the second substrate at positions other than the dividing line.

6. The method according to claim 1,
wherein the forming the structure includes forming the structure together with constituent parts of the first substrate at positions other than the dividing line.

7. A bonded substrate comprising:
a first substrate;
a second substrate bonded to the first substrate;
a contact terminal on an end portion of the first substrate in a short side direction of the first substrate, the contact terminal contactable with an external terminal;
a protective layer covering the first substrate and the second substrate;
a cutoff portion in a part of the first substrate along a dividing line in a longitudinal direction of the bonded substrate, the cutoff portion configured to expose the second substrate in a plan view of the bonded substrate viewed from the first substrate; and
a structure connecting the first substrate and the second substrate, the structure disposed between the cutoff portion and the contact terminal in a longitudinal direction orthogonal to the short side direction.

8. The bonded substrate according to claim 7,
wherein the protective layer is a liquid contact film covering the first substrate and the second substrate.

9. The bonded substrate according to claim 7,
wherein a length of the structure along the dividing line is in a range from 10 to 100 μm.

10. The bonded substrate according to claim 7,
wherein the structure is formed together with constituent parts of the second substrate at positions other than the dividing line.

11. The bonded substrate according to claim 7,
wherein the cutoff portion is at a central portion in a longitudinal direction of the first substrate in the dividing line.

12. A liquid discharge head comprising:
the bonded substrate according to claim 7.

13. A bonded substrate comprising:
a first substrate;
a second substrate bonded to the first substrate;
a contact terminal on an end portion of the first substrate in a short side direction of the first substrate, the contact terminal contactable with an external terminal;
a protective layer covering the first substrate and the second substrate;
a cutoff portion in a part of the second substrate along a dividing line in a longitudinal direction of the bonded substrate, the cutoff portion configured to expose the first substrate in a plan view of the bonded substrate viewed from the second substrate; and
a structure connecting the first substrate and the second substrate, the structure disposed between the cutoff portion and the contact terminal in a longitudinal direction orthogonal to the short side direction.

14. The bonded substrate according to claim 13,
wherein the protective layer is a liquid contact film covering the first substrate and the second substrate.

15. The bonded substrate according to claim 13,
wherein a length of the structure along the dividing line is in a range from 10 to 100 μm.

16. The bonded substrate according to claim 13,
wherein the structure is formed together with constituent parts of the second substrate at positions other than the dividing line.

17. The bonded substrate according to claim 13,
wherein the cutoff portion is at a central portion in a longitudinal direction of the first substrate in the dividing line.

18. A liquid discharge head comprising:
the bonded substrate according to claim 13.
